(19) United States
(12) Patent Application Publication
(10) Pub. No.: US 2026/0044090 A1
(43) Pub. Date: Feb. 12, 2026

(54) SEMICONDUCTOR PROCESSING TOOL CLUSTER WITH REDUCED INTERFERENCE BETWEEN TOOLS

(71) Applicant: Taiwan Semiconductor Manufacturing Company, Ltd., Hsinchu (TW)

(72) Inventors: Chih-Hong Huang, New Taipei (TW); Feng-Tzu Hsu, Hsinchu (TW); Chien Te Li, Hsinchu (TW); Jia-Hau Shiau, Yilan (TW)

(21) Appl. No.: 18/796,829

(22) Filed: Aug. 7, 2024

(51) Int. Cl. G03F 7/00; G03F 7/42; H01L 21/3065; H01L 21/67

(52) U.S. Cl. CPC G03F 7/70808; G03F 7/42; G03F 7/70991; H01L 21/3065; H01L 21/67242

(57) ABSTRACT

A semiconductor processing tool cluster includes: a first semiconductor processing tool including a microwave generator comprising at least one magnet and configured to perform semiconductor wafer processing using microwave energy produced by the microwave generator; a second processing tool configured to perform semiconductor wafer processing using a plasma generated in a process chamber of the second processing tool; and a magnetic field shield comprising at least one closed annular shell disposed around the microwave generator of the first semiconductor processing tool, the at least one closed annular shell comprising a material with magnetic permeability that is greater than the magnetic permeability of free space. In some cases, a magnetometer may be arranged to measure a magnetic field at a location outside of the magnetic field shield, and a circuit performs a remedial action based on a magnetic field measurement output by the magnetometer.

### BACKGROUND

The following relates to semiconductor processing tool clusters, semiconductor processing tools, plasma stripping tools, and the like.

A semiconductor processing tool cluster is made up of two or more semiconductor processing tools. Each tool typically includes a processing chamber that enables the semiconductor wafer to be placed into a controlled environment, such as a vacuum environment, and exposed to materials (e.g., gases, sputtered material, or so forth), energies (e.g., radio frequency or RF energy, microwave energy, or so forth), and/or combinations thereof (e.g., an RF-excited gas forming a plasma) in order to perform processing operations such as etching, deposition, photoresist stripping, and/or so forth.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 diagrammatically illustrates a top view of a semiconductor processing tool cluster that includes a first semiconductor processing tool that utilizes microwave energy to process semiconductor wafers, and second semiconductor processing tool that utilizes radio frequency (RF) generated plasma; and further illustrates a side sectional view of the first semiconductor processing tool including a microwave generator with a magnetic field shield.

FIG. 2A diagrammatically illustrates a perspective view of a microwave generator of a semiconductor processing tool that utilizes microwave energy to process semiconductor wafers; and FIG. 2B diagrammatically illustrates the perspective view of the microwave generator of FIG. 2A with a magnetic field shield.

FIGS. 3A and 3B diagrammatically illustrate top views of the first semiconductor processing tool that utilizes microwave energy to process semiconductor wafers and the second semiconductor processing tool that utilizes RF generated plasma, and further diagrammatically depicts the plasma and the magnetic field for: the magnetic field generator without the magnetic field shield (FIG. 3A); and the magnetic field generator with the magnetic field shield (FIG. 3B).

FIG. 4 diagrammatically illustrates a perspective view of the magnetic field shield of FIGS. 1, 2B, and 3B in accordance with a nonlimiting illustrative embodiment.

FIG. 5 diagrammatically illustrates a top view of the magnetic field shield of FIGS. 1, 2B, and 3B in accordance with a nonlimiting illustrative embodiment in which the magnetic field shield has an open bottom.

FIG. 6 diagrammatically illustrates a top view of the magnetic field shield of FIGS. 1, 2B, and 3B in accordance with a nonlimiting illustrative embodiment in which the magnetic field shield has an enclosed bottom.

FIGS. 7 and 8 diagrammatically illustrate perspective views of the magnetic field shield of FIGS. 1, 2B, and 3B in accordance with two alternative illustrative embodiments presented as further nonlimiting examples.

FIG. 9 diagrammatically illustrates a perspective view of the magnetic field shield of FIGS. 1, 2B, and 3B in accordance with a further nonlimiting example, in which the magnetic field shield includes multiple (illustrative three) layers.

FIG. 10 diagrammatically illustrates a perspective view of a microwave generator of a semiconductor processing tool that utilizes microwave energy to process semiconductor wafers, with a magnetic field shield, and further diagrammatically illustrates a magnetometer arranged to detect a problem with the magnetic field shield and a circuit configured to perform a remedial action based on a magnetic field measurement output by the magnetometer.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A semiconductor processing tool cluster includes such semiconductor processing tools along with an automated mechanism for transfer of semiconductor wafers between the semiconductor processing tools of the cluster under controlled conditions. For example, the semiconductor processing tool cluster may include a load lock for receiving a batch of semiconductor wafers. The load lock is evacuated and wafers are transferred through vacuum-tight passageways via a robotic wafer handler, conveyor belts, and/or other automated mechanisms. The semiconductor processing tool cluster can be designed for rapid and efficient processing of batches of semiconductor wafers, sometimes including duplicate tools to further enhance wafer throughout, and the automation minimizes exposure to atmosphere and particulates.

The semiconductor processing tools of a semiconductor processing tool cluster are arranged in relatively close proximity to one another, to facilitate transfer of semiconductor wafers between the tools. For example, the tools of the semiconductor processing tool cluster may be arranged in a ring, and wafer transfer between the tools is performed in a central area within the ring, e.g., using a centrally placed robot, a centrally placed rotating carousel, and/or other automated wafer handling hardware. In another cluster configuration, the tools of the semiconductor processing tool cluster may be arranged in a line with a conveyor running between the tools and suitable robotic or other mechanisms for transferring semiconductor wafers to and from the linear conveyor. Variant linear arrangements may one or more conveyor turns, for example a 90-degree turn, to provide a more compact arrangement for the semiconductor processing tool cluster. These are merely some nonlimiting illustrative cluster layouts.

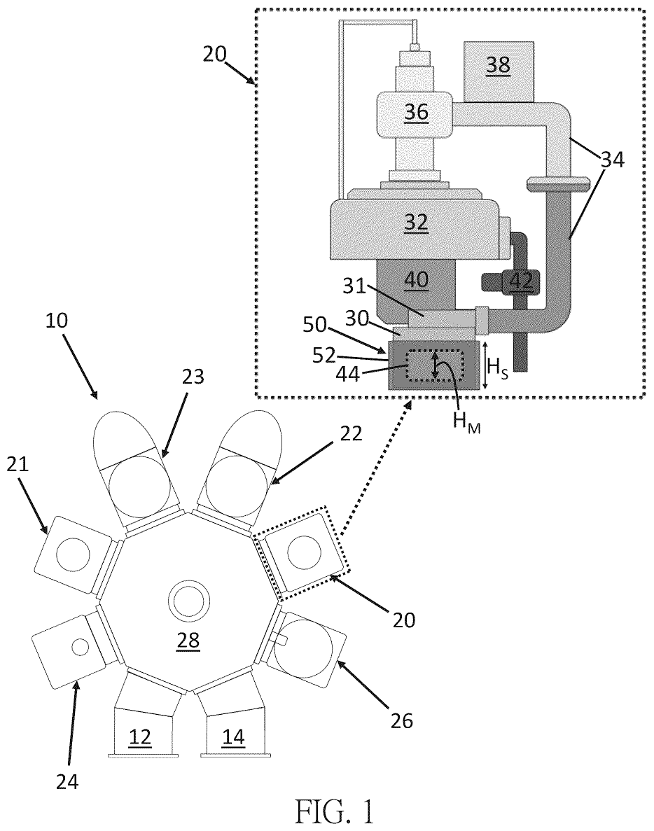

With reference to FIG. 1, a nonlimiting illustrative example of a semiconductor processing tool cluster 10 arranged in a ring configuration is diagrammatically shown via a top view. The semiconductor processing tool cluster 10 includes two load locks 12 and 14, and a plurality of semiconductor processing tool including: a photoresist stripping tool 20; a second photoresist stripping tool 21; a plasma etching chamber 22; a second plasma etching chamber 23; a cooling chamber 24; and a robotic orientation adjustment chamber 26. The semiconductor processing tools 20, 21, 22, 23, 24, and 26 along with the two load locks 12 and 14 are arranged in a ring around a central wafer transfer region 28 that contains conveyors, robots, a carousel, and/or other automated wafer handling hardware for transferring semiconductor wafers between the various semiconductor processing tools 20, 21, 22, 23, 24, 26 in accordance with a predefined (e.g., preprogrammed) semiconductor device or integrated circuit (IC) fabrication workflow. The inclusion of two photoresist stripping tools 20 and 21, and two etching chambers 22 and 23, can advantageously increase the semiconductor wafer throughput of the semiconductor processing tool cluster 10 by enabling, for example, two semiconductor wafers to simultaneously undergo an etching process, and two semiconductor wafers to simultaneously undergo photoresist stripping.

As a nonlimiting illustrative example, a (partial) semiconductor device or IC fabrication workflow performed by the semiconductor processing tool cluster 10 may include: receiving a semiconductor wafer with a patterned photoresist layer disposed on the principal surface thereof at one of the load locks 12 or 14; moving the semiconductor wafer from the load lock into one of the etching tools 22 or 23; performing patterned plasma etching of material of the semiconductor wafer through openings in the patterned photoresist layer using the etching tool; after the etching, transferring the semiconductor wafer to one of the photoresist stripping tools 20 or 21; stripping the patterned photoresist from the principal surface of the wafer using the photoresist stripping tool; and after the photoresist stripping, transferring the wafer back to one of the load locks 12 or 14 for removal from the semiconductor processing tool cluster 10. Optionally, such a workflow may include transferring the semiconductor wafer into the cooling chamber 24 for some time interval if the wafer is too hot for the next step, and/or transferring the wafer into the orientation adjustment chamber 26 to properly position the wafer for insertion into a next tool used in the workflow. It will be understood that the workflow just described is merely one nonlimiting illustrative example, and that more generally a semiconductor processing tool cluster can be configured by inclusion of suitable tools and robotic wafer handling apparatuses to perform a range of different types of processing workflows.

As previously noted, while FIG. 1 illustrates a semiconductor processing tool cluster 10 arranged in a ring configuration, it could have other layout configurations, such as a linear configuration, an “L”-shaped configuration (i.e., combination of two linear sections meeting at a 90° angle), or so forth. Regardless of the particular layout that is employed, the semiconductor processing tool cluster 10 places the constituent semiconductor processing tools 20, 21, 22, 23, 24, 26 in proximity to one another to facilitate transfer of semiconductor wafers between the tools 20, 21, 22, 23, 24, 26 under a controlled environment (e.g., transfer under vacuum as an illustrative example).

In the illustrative example, the semiconductor processing tool cluster 10 places the photoresist stripping tool 20 and the plasma etching chamber 22 close to each other; and likewise places the photoresist stripping tool 21 and the plasma etching chamber 23 close to each other. It is recognized herein that this proximate placement can raise a difficulty. If the photoresist stripping tool 20 or 21 employs a microwave generator, this can produce a magnetic field that can interfere with the plasma generated in the neighboring plasma etching chamber 22 or 23, respectively. As disclosed herein, based on this insight the microwave generator of the photoresist stripping tool 20 or 21 is provided with a magnetic field shield, which blocks the magnetic field produced by the microwave generator of the photoresist stripping tool 20 or 21 from interfering with the etching performed by the generator neighboring plasma etching chamber 22 or 23, respectively.

To show this, FIG. 1 further diagrammatically illustrates a side sectional view of the photoresist stripping tool 20. (The photoresist stripping tool 21 may have a similar configuration). As seen in this side sectional view, the photoresist stripping tool 20 includes a microwave generator 30 with an output coupler 31, a processing chamber 32, and microwave coupling hardware including a waveguide 34 with one end coupling into the output coupler 31 of the microwave generator 30, and an applicator 36 connected to the other end of the waveguide 34 and connected to guide microwave energy produced by the microwave generator 30 from the waveguide 34 into the process chamber 32. A tuner 38 may be provided to tune the frequency of the microwave energy before it is injected into the process chamber 32 by the applicator 36. The illustrative the photoresist stripping tool 20 further includes a lamp module 40, and a throttle valve 42 for controlling solvent flow in the process chamber 32. In operation, microwave energy produced by the microwave generator 30 is guided into the process chamber 32 by the microwave energy transfer components 34, 36, 38, where the microwave energy (optionally along with optical energy from the optional lamp module 40) heats and agitates a solvent (chosen based on the type of photoresist) to provide efficient dissolution and removal (i.e., stripping) of a photoresist layer disposed on the semiconductor wafer. It will be understood that the photoresist stripping tool 20 and here-described operation thereof is merely one nonlimiting illustrative example, and the photoresist stripping tool may have other configurations that utilize microwave energy produced by the microwave generator 30 in performing photoresist stripping.

As diagrammatically shown in FIG. 1, the microwave generator 30 includes at least one (diagrammatically indicated) magnet 44 that provides a magnetic field for manipulating electrons in a manner that causes the electrons to produce microwave energy. As one nonlimiting illustrative example, the microwave generator 30 may comprise a magnetron including a vacuum tube (not shown) and a magnet, or a pair of permanent magnets, (diagrammatically indicated by the at least one magnet 44), with the anode and cathode of the vacuum tube and the magnet(s) 44 mutually arranged to cause electrons flowing from the cathode to the anode to follow a tortuous and/or circulating path that causes the electrons to emit microwave energy. By way of a few nonlimiting illustrative examples, the magnet(s) 44 may comprise a permanently magnetized material such as steel, ferrite, a neodymium-based material, samarium-cobalt (SmCo), or so forth. While permanent magnet(s) are described, it is also contemplated for the magnet(s) 44 to be implemented as an electromagnet. In some nonlimiting illustrative embodiments, the microwave energy generated by the microwave generator 30 may be in the gigahertz range, and the microwave frequency may optionally be tuned by the optional tuner 38 to a desired microwave frequency for injection by the applicator 36 to perform the microwave-assisted photoresist stripping.

The one or more magnets 44 of the microwave generator 30 of the example photoresist stripper tool 20 produce a stray magnetic field. The neighboring plasma etching chamber 20 produces a plasma in its process chamber. A plasma comprises ionized atoms and/or molecules, and these are charged particles that can be affected by the magnetic field produced by the microwave generator 30, and more particularly by its magnet(s) 44. The charged particles in the plasma will be affected by the magnetic force, causing the plasma concentration to be unevenly distributed, resulting in uneven etching rate. It is noted that while plasma etching chambers 22 and 23 are described as illustrative examples, more generally any semiconductor processing tool of the cluster that performs semiconductor wafer processing using a plasma generated in a process chamber may be similarly affected by the stray magnetic field from the photoresist stripper tool 20. As another example (not illustrated), the affected semiconductor processing tool that performs semiconductor wafer processing using a plasma generated in a process chamber could be a plasma deposition chamber that employs a plasma generated in a process chamber in a deposition process, such as a plasma-enhanced chemical vapor deposition (PECVD) tool. Hence, the illustrative plasma etching chamber 22 is also more generally referred to herein as a second semiconductor processing tool 22 that utilizes radio frequency (RF) generated plasma.

Likewise, it is further noted that while the photoresist stripping tools 20 and 21 are described as illustrative examples, more generally any semiconductor processing tool of the cluster that performs semiconductor wafer processing using microwave energy produced by a microwave generator 30 may similarly produce a stray magnetic field from the microwave generator 30 that could adversely affect uniformity of semiconductor wafer processing performed in another tool of the cluster that that performs semiconductor wafer processing using a plasma generated in a process chamber. As further examples (not illustrated), the semiconductor processing tool of the cluster that performs semiconductor wafer processing using microwave energy produced by a microwave generator 30 could be a microwave annealing tool, a microwave drying and/or curing tool, or so forth. Hence, the illustrative photoresist stripper tool 20 is also more generally referred to herein as a first semiconductor processing tool 20 that utilizes microwave energy to process semiconductor wafers.

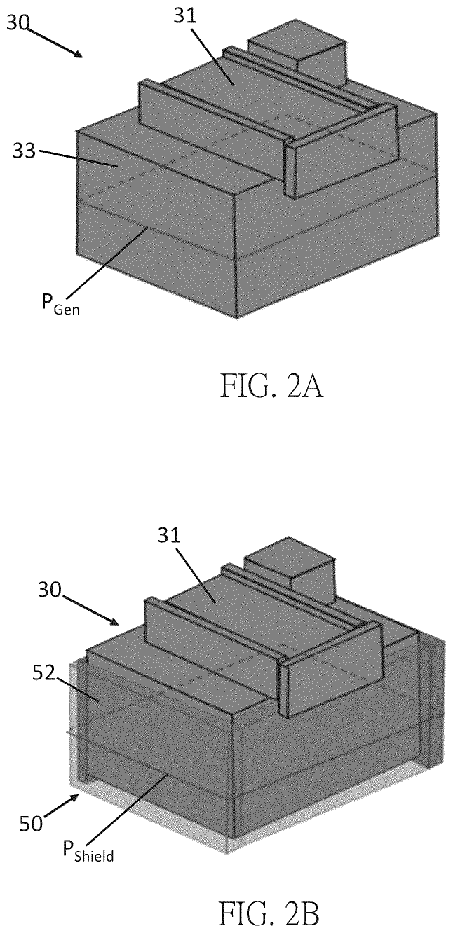

With continuing reference to FIG. 1 and with further reference to FIGS. 2A and 2B, a magnetic field shield 50 comprises at least one closed annular shell 52 disposed around the microwave generator 30. The at least one closed annular shell 52 comprises a material with magnetic permeability μ that is greater than the magnetic permeability of free space (μ₀=1.2567×10⁻⁶ H/m). In general, the higher the magnetic permeability μ of the at least one closed annular shell 52, the more effective the magnetic shielding will be. In some embodiments, the at least one closed annular shell 52 comprises a material with magnetic permeability μ that is at least 1×10⁻⁴ H/m (i.e., 100×10⁻⁶ H/m), which is approximately 80 times higher than the magnetic permeability μ₀ of free space. Some nonlimiting illustrative materials that may be used for the at least one closed annular shell 52 include: nickel (μ=125×10⁻⁶ H/m); ferrite (μ=800×10⁻⁶ H/m); steel (μ=875×10⁻⁶ H/m); electric furnace steel (μ=5×10⁻³ H/m); permalloy (p typically on the order of 0.01 H/m); or mu-metal (u typically on the order of 0.025 H/m). Again, these are merely some nonlimiting illustrative materials that can be suitably used for the at least one closed annular shell 52 of the magnetic field shield 50.

The foregoing can alternatively be expressed in terms of relative magnetic permeability (μᵣ), which is relative to the vacuum magnetic permeability according to:

$${μ}_{r} = \frac{μ}{{μ}_{0}} \qquad ( 1 )$$

where μ is the dielectric material magnetic permeability, and μ₀ is the magnetic permeability of free space, i.e., vacuum (μ₀=1.2567×10⁻⁶ H/m). In terms of relative permeability, the at least one closed annular shell 52 comprises a material with relative magnetic permeability μᵣ>1. In general, the higher the relative magnetic permeability μᵣ of the at least one closed annular shell 52, the more effective the magnetic shielding will be. In some embodiments, the at least one closed annular shell 52 comprises a material with relative magnetic permeability μᵣ≥80.

With particular reference to FIGS. 2A and 2B, the microwave generator 30 is shown in a perspective isolation view in FIG. 2A. The microwave generator 30 includes the output coupler 31 as previously described for coupling microwave energy generated by the microwave generator 30 into the waveguide 34 (see FIG. 1). The microwave generator 30 further includes a housing 33 (labeled only in FIG. 2A) that encloses or houses internal components of the microwave generator 30. These internal components include the at least one magnet 44 (see FIG. 1), and in the case of a magnetron implementation further includes a vacuum tube with suitably designed anode and cathode (components not shown). The housing 33 may in some embodiments be made of a material such as steel having magnetic permeability μ that is greater than the magnetic permeability μ₀ of free space. However, the housing 33 has relatively thin walls, and/or may have gaps, such that the housing 33 of the microwave generator 30 is insufficient to prevent the stray magnetic field from exiting the housing 33. Hence, the magnetic field shield 50 is a separate component from the housing 33 of the microwave generator 30, and is shown in FIG. 2B which depicts a perspective view of the microwave generator 30 with the at least one closed annular shell 52 of the magnetic field shield 50 disposed around and encircling the microwave generator 30. The magnetic field shield 50 blocks the magnetic field produced by the microwave generator 30 from interfering with the etching (or other semiconductor wafer processing) performed in the neighboring tool that uses a plasma (e.g., the plasma etching chamber 22 in the illustrative examples).

To enable this arrangement, the magnetic field shield 50 (and more particularly the at least one closed annular shell 52) has an inner perimeter length L_{shield} indicated in FIG. 2B which is larger than an outer perimeter length L_{Gen} of (the housing 33 of) the microwave generator 30 as indicated in FIG. 2A. Furthermore, to enable the magnetic field shield 50 to provide the magnetic shielding of the stray magnetic field produced by the at least one magnet 44 of the microwave generator 30, as shown in the side sectional view of the photoresist stripper 20 shown in FIG. 1, the at least one closed annular shell 52 of the magnetic field shield 50 has a height (H_{S}) that is greater than or equal to a height (H_{M}) of the at least one magnet 44 of the microwave generator 30.

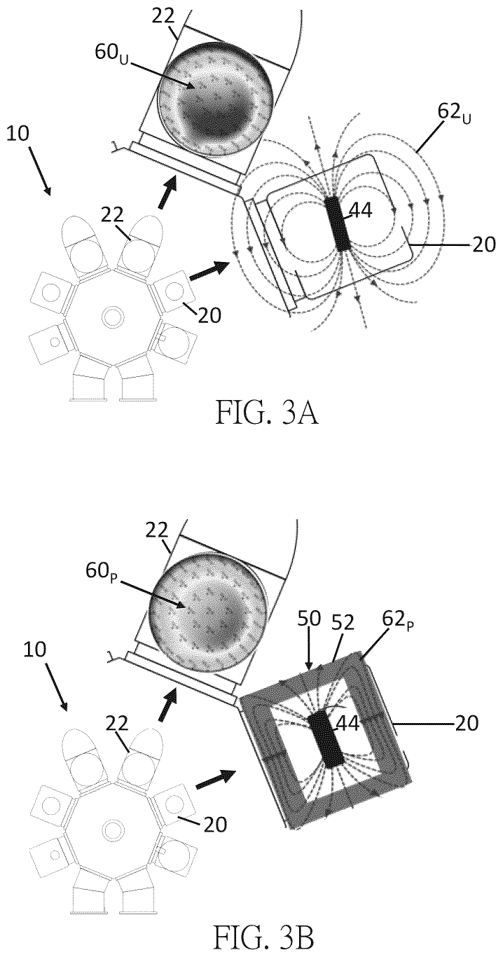

With reference now to FIGS. 3A and 3B, operation of the magnetic field shield 50 is further described. FIGS. 3A and 3B diagrammatically illustrate top views of the first semiconductor processing tool 20 that utilizes microwave energy to process semiconductor wafers, and the second semiconductor processing tool 22 that utilizes RF generated plasma.

FIG. 3A further diagrammatically depicts a plasma 60_{U} (by way of a diagrammatically depicted plasma density field) produced in the process chamber of the second semiconductor processing tool 22, and a magnetic field 62_{U} (by way of diagrammatically depicted magnetic field lines) produced by the at least one magnet 44 of the microwave generator (not shown in FIG. 3A) of the first semiconductor processing tool 20, with the microwave generator operating without the magnetic field shield. In the reference numbers 60_{U} and 62_{U} of FIG. 3A, the subscript “U” indicates “unprotected”, that is, the plasma 60_{U} of the second semiconductor processing tool 22 is not protected from the stray magnetic field 60_{U} produced by the at least one magnet 44 of the microwave generator of the first semiconductor processing tool 20.

FIG. 3B further diagrammatically depicts a plasma 60_{P} (by way of a diagrammatically depicted plasma density field) produced in the process chamber of the second semiconductor processing tool 22, and a magnetic field 62_{P} (by way of diagrammatically depicted magnetic field lines) produced by the at least one magnet 44 of the microwave generator (not shown in FIG. 3B) of the first semiconductor processing tool 20, with the microwave generator operating with the magnetic field shield 50. In the reference numbers 60_{P} and 62_{P} of FIG. 3B, the subscript “P” indicates “protected”, that is, the plasma 60_{P} of the second semiconductor processing tool 22 is protected by the magnetic field shield 50 from the stray magnetic field 60_{P} produced by the at least one magnet 44 of the microwave generator of the first semiconductor processing tool 20.

As seen in FIG. 3A, the unprotected magnetic field 62_{U} extends a substantial distance away from the first semiconductor processing tool 20, with a portion of the unprotected magnetic field 62_{U} extending to the second semiconductor processing tool 22, where it can affect the unprotected plasma 60_{U}. The magnetic field B produces a Lorentz force on the charged particles of the unprotected plasma 60_{U} according to the cross-product:

$$\overline{F} = q \overline{v} \times \overline{B} \qquad ( 2 )$$

where F̅ is the Lorentz force on the charged particle of charge q and moving at velocity v̅. The Lorentz force can shift the distribution of charged particles making up the unprotected plasma 60_{U}, leading to an overall shift in the spatial distribution of the plasma. The plasma-generating components of the second semiconductor processing tool 22 and the operational parameters (e.g., the RF electrodes and RF voltage applied thereto, the flow of gas into the processing chamber of the second semiconductor processing tool 22, and so forth) are optimized to provide a spatially uniform plasma at least over the portion of the plasma volume that interacts with the semiconductor wafer. This optimization is performed under the assumption that there is no external magnetic field being applied.

Hence, the unprotected magnetic field 62_{U} from the neighboring first semiconductor processing tool 20 distorts the unprotected plasma 60_{U}, leading to nonuniform interaction of the plasma with the semiconductor wafer. In the illustrative example in which the second semiconductor processing tool 22 is an etching tool, the portion of the unprotected magnetic field 62_{U} extending into the region of the plasma 60_{U} distorts the unprotected plasma 60_{U}, leading to spatially nonuniform PECVD deposition and consequent thickness variation of the PECVD-deposited layer over the area of the semiconductor wafer. These are nonlimiting illustrative examples.

As seen in FIG. 2B, providing the magnetic field shield 50 comprising the at least one closed annular shell 52 disposed around the microwave generator 30 (and more particularly around the at least one magnet 44 thereof) modifies, and more particularly spatially restricts, the protected magnetic field 62_{P} to an area mostly or entirely within the at least one closed annular shell 52. No portion (or a negligibly small portion) of the protected magnetic field 62_{P} extends into the volume of the protected plasma 60_{P} being produced in the second semiconductor processing tool 22. Accordingly, the protected plasma 60_{P} is not distorted by the protected magnetic field 62_{P}, and so the spatial uniformity of the etching (or PVCVD deposition, or other plasma-assisted semiconductor wafer processing) is unaffected by the protected magnetic field 62_{P} which is spatially constrained by the magnetic field shield 50. Put another way, the magnetic field shield 50 blocks the (protected) magnetic field 62_{P} produced by the microwave generator from interfering with the etching (or PVCVD deposition, or so forth) performed using the (protected) plasma 60_{P} generated in the second (e.g., etching) chamber.

In one way of viewing the operation of the magnetic field shield 50, the air and the material of the at least one closed annular shell 52 (e.g., mu-metal, permalloy, steel, iron, nickel, or another material with μᵣ>1, and in some embodiments with μᵣ≥80) can be regarded as parallel magnetic circuit. The magnetic lines will follow the path of lower magnetic resistance (namely the at least one closed annular shell 52 due to its high value of magnetic permeability u, compared with the free space permeability μ₀ of the air). Hence, the portion of the unprotected magnetic field 62_{U} (see FIG. 3A) that reaches the second semiconductor processing tool 22 is instead the protected magnetic field 62_{P} which is confined by the at least one closed annular shell 52, as seen in FIG. 3B.

The effectiveness of the magnetic field shield 50 in confining the magnetic field of the at least one magnet 44 of the microwave generator 30 is controlled by the magnetic resistance (also known as magnetic reluctance) of the at least one closed annular shell 52. The magnetic resistance R of the at least one closed annular shell 52 is given as:

$$ℛ = \frac{{L}_{S h i e l d}}{μ A} \qquad ( 3 )$$

where L_{shield} is the perimeter length of the at least one closed annular shell 52 (notated in FIG. 2B), μ is the magnetic permeability of the material of the at least one closed annular shell 52, and A is the cross-sectional area of (the wall of) the at least one closed annular shell 52. As previously noted, perimeter length L_{shield} is largely controlled by the perimeter length L_{Gen} of (the housing 33) of the microwave generator 30 (see FIGS. 2A and 2B) in that L_{shield}>L_{Gen} is the condition for the microwave generator 30 to fit in the closed annular shell 52. The magnetic resistance [symbol] of the at least one closed annular shell 52 can thus be minimized (and thereby the magnetic field shielding effectiveness maximized) principally by increasing the magnetic permeability μ by using a material with large magnetic permeability, and by increasing the cross-sectional area A of (the wall of) the at least one closed annular shell 52.

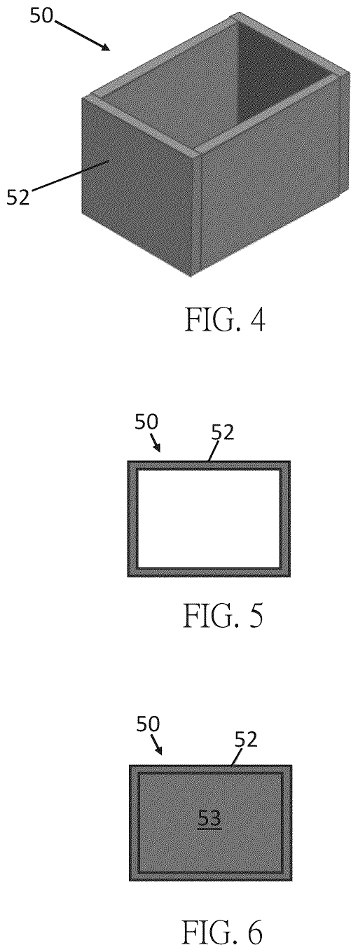

With reference now to FIGS. 4, 5, and 6, some suitable configurations for the illustrative magnetic field shield 50 are described. FIG. 4 depicts an isolation perspective view of the magnetic field shield 50, including the at least one closed annular shell 52 (which in this embodiments is a single closed annular shell 52). As shown in FIGS. 5 and 6, the magnetic field shield 50 may, or may not, include a bottom. FIG. 5 shows a top view of an embodiment of the magnetic field shield 50 that does not include a bottom. FIG. 6 shows a top view of an embodiment of the magnetic field shield 50 that does include a bottom 53 comprising a material with magnetic permeability that is greater than the magnetic permeability of free space (that is, a material with μᵣ>1). The bottom 53 is connected with the at least one closed annular shell 52 to form a container (with a bottom) within which the at least one magnet 44 of the microwave generator 30 is disposed. In some embodiments the bottom 53 comprises a material with relative magnetic permeability μᵣ>80. In some embodiments, the bottom 53 is made of the same material as the closed annular shell 52. In some such embodiments, the closed annular shell 52 and the bottom 53 may be formed as a single unitary piece.

Inclusion of the bottom 53 (as in the embodiment of FIG. 6) may provide improved magnetic field shielding by blocking the magnetic field of the at least one magnet 44 of the microwave generator 30 from leaking underneath the bottom edge of the at least one closed annular shell 52.

Omission of the bottom (as in the embodiment of FIG. 5) may simplify placement of the magnetic field shield around the microwave generator 30, especially if the microwave generator 30 is heavy and rests on the floor.

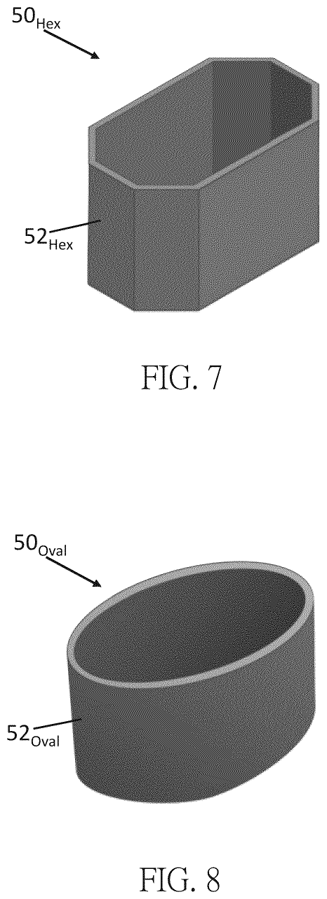

In the preceding examples, the magnetic field shield 50 comprises the single closed annular shell 52 with a square perimeter, i.e., having four sides. More generally, the at least one closed annular shell of the magnetic field shield may have a triangular, rectangular, or higher-order polynomial perimeter, or an oval perimeter, or other geometry. Some further nonlimiting illustrative examples are given in FIGS. 7 and 8.

FIG. 7 illustrates a perspective view of a magnetic field shield 50_{Hex} which has a single closed annular shell 52_{Hex} that is octagonal, that is, has eight sides.

FIG. 8 illustrates a perspective view of a magnetic field shield 50_{Oval} which has a single closed annular shell 52_{Oval} that is oval in shape.

In the preceding examples, the magnetic field shield 50, 50_{Hex}, or 50_{Oval} comprises a single closed annular shell 52, 52_{Hex}, or 52_{Oval}, respectively. However, in other embodiments the magnetic field shield may include at least one closed annular shell that includes two, three, four, or more nested closed annular shells disposed around the microwave generator 30.

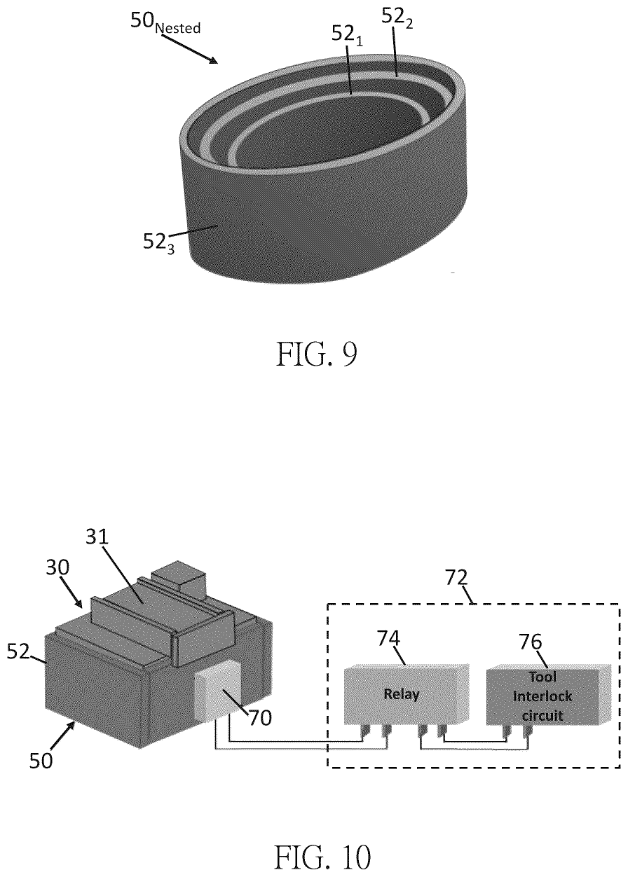

With reference to FIG. 9, an example is shown of a (nested) magnetic field shield 50_{Nested} which includes three nested closed annular shells 52₁, 52₂, and 52₃. In this example, the innermost closed annular shell 52₁ is nested inside the closed annular shell 52₂; and in turn the closed annular shell 52₂ is nested inside the outermost closed annular shell 52₃. An advantage of a nested magnetic field shield which includes two or more nested closed annular shells is that, referring back to Equation (3) which presents the magnetic resistance

$$ℛ = \frac{{L}_{S h i e l d}}{μ A}$$

of the at least one closed annular shell, the cross-sectional area of the at least one closed annular shell is increased. For example, if the individual closed annular shells 52₁, 52₂, and 52₃ have respective cross-sectional areas A₁, A₂, and A₃, then the three nested closed annular shells 52₁, 52₂, and 52₃ have a total cross-sectional area of A₁+A₂+A₃, yielding a lower magnetic resistance for the three nested closed annular shells 52₁, 52₂, 52₃ of:

$$ℛ = \frac{{L}_{S h i e l d}}{μ ( {A}_{1} + {A}_{2} + {A}_{3} )} \qquad ( 4 )$$

compared with the magnetic resistance [symbol] of any one closed annular shell by itself.

A further benefit of nesting two or more closed annular shells 52₁, 52₂, and 52₃ is that this arrangement can enhance the operational lifetime of the magnetic field shield. One failure mechanism of the magnetic field shield is magnetization of the high magnetic permeability material of the magnetic field shield. This can occur over time if the at least one magnet 44 is a permanent magnet (or permanent magnets) that continually apply a magnetic field of the same orientation passing through the closed annular shell. As the shell material becomes magnetized, its magnetic field shielding capacity is reduced. In a nested arrangement such as that of FIG. 9, this failure mechanism is suppressed. For example, when initially installed the innermost closed annular shell 52₁ will capture most or all of the magnetic field from the magnet(s) 44. The two outer closed annular shells 52₂ and 52₃ are thus not exposed to the magnetic field from the magnet(s) 44, and hence will not be prone to becoming magnetized. If, over time, the innermost closed annular shell 52₁ becomes magnetized and has its shielding effectiveness reduced, the middle closed annular shell 52₂ can then capture the magnetic field that passes through the innermost closed annular shell 52₁. As more shells are nested (e.g., adding the outermost closed annular shell 52₃) further increases the operating lifetime of the magnetic field shield.

It should be noted that this failure mechanism in which the at least one closed annular shell of the magnetic field shield becomes magnetized can advantageously be reversed by applying degaussing to remove the magnetization of the annular shell.

With reference now to FIG. 10, in some embodiments the effectiveness of the magnetic field shield 50 for blocking the magnetic field produced by the microwave generator 30 of the first semiconductor processing tool 20 from interfering with the plasma used in the etching (or other processing) performed by the second semiconductor processing tool 22 can be actively monitored. FIG. 10 illustrates a perspective view of the microwave generator 30 and the magnetic field shield 50, which has already been described with reference to FIG. 2B. The embodiment of FIG. 10 further includes a magnetometer 70 arranged to measure a magnetic field at a location outside of the magnetic field shield 50, and a circuit 72 configured to perform a remedial action based on a magnetic field measurement output by the magnetometer 70. The magnetometer 70 may be a Hall effect sensor, for example, although other types of magnetometers are contemplated. The illustrative magnetometer 70 is attached to the outside of the closed annular shell 52 of the magnetic field shield 50, but it is alternatively contemplated to place the magnetometer 70 in another location that is outside of the magnetic field shield 50. The illustrative circuit 72 includes a relay 74 and a tool interlock circuit 76 which shuts off the second semiconductor processing tool 22 if the measured magnetic field indicates the plasma of the second semiconductor processing tool 22 is no longer being sufficiently well-protected from the magnet 44 by the magnetic field shield 50. In one suitable implementation according to a nonlimiting illustrative example, using the principle of the Hall sensor (or other magnetometer 70), the magnetic field intensity is detected and converted into a voltage signal to control the normally closed relay 74 of the interlock 76 of the tools, so that once the magnetic field shielding provided by the magnetic field shield 50 fails, the relay 74 operates to block the interlock circuit of the machines. This is merely a nonlimiting illustrative example. More generally, the magnetometer 70 is arranged to measure a magnetic field at a location outside of the magnetic field shield 50, and the circuit 72 is configured to perform a remedial action based on a magnetic field measurement output by the magnetometer 70 (e.g., based on the magnetic field measurement exceeding a maximum permissible threshold value). The remedial action can be shutdown of a tool by an interlock as in the illustrative embodiment, or could be a less aggressive remedial action such as turning on a warning light or displaying a textual warning message on a display device indicating that the magnetic field shield 50 may no longer be providing sufficient magnetic field shielding.

In the following, some further embodiments are described.

In a nonlimiting illustrative embodiment, a semiconductor processing method includes: using a photoresist stripping tool of a semiconductor processing tool cluster, performing photoresist stripping using microwave energy produced by a microwave generator of the photoresist stripping tool; using an etching tool of the semiconductor processing tool cluster, performing etching using a plasma generated by the etching tool; during the etching, blocking a magnetic field produced by the microwave generator from interfering with the etching using a magnetic field shield comprising at least one closed annular shell disposed around the microwave generator; measuring a magnetic field at a location outside of the magnetic field shield; and performing a remedial action in response to the measured magnetic field exceeding a threshold.

In a nonlimiting illustrative embodiment, a semiconductor processing tool cluster includes: a first semiconductor processing tool including a microwave generator comprising at least one magnet and configured to perform semiconductor wafer processing using microwave energy produced by the microwave generator; a second processing tool configured to perform semiconductor wafer processing using a plasma generated in a process chamber of the second processing tool; and a magnetic field shield comprising at least one closed annular shell disposed around the microwave generator of the first semiconductor processing tool, the at least one closed annular shell comprising a material with magnetic permeability that is greater than the magnetic permeability of free space.

In a nonlimiting illustrative embodiment, a semiconductor processing tool includes: a microwave generator comprising a housing and at least one magnet disposed in the housing; a process chamber; a waveguide and an applicator connected to guide microwave energy produced by the microwave generator into the process chamber; and a magnetic field shield comprising at least one closed annular shell disposed around the microwave generator of the first semiconductor processing tool. The at least one closed annular shell comprises a material with magnetic permeability of at least 1×10⁻⁴ H/m.

In a nonlimiting illustrative embodiment, a semiconductor processing method includes: using a photoresist stripping tool of a semiconductor processing tool cluster, performing photoresist stripping using microwave energy produced by a microwave generator of the photoresist stripping tool; using an etching tool of the semiconductor processing tool cluster, performing etching using a plasma generated by the etching tool; and during the etching, blocking a magnetic field produced by the microwave generator from interfering with the etching using a magnetic field shield comprising at least one closed annular shell disposed around the microwave generator.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor processing method comprising:
using a photoresist stripping tool of a semiconductor processing tool cluster, performing photoresist stripping using microwave energy produced by a microwave generator of the photoresist stripping tool;
using an etching tool of the semiconductor processing tool cluster, performing etching using a plasma generated by the etching tool; and
during the etching, blocking a magnetic field produced by the microwave generator from interfering with the etching using a magnetic field shield comprising at least one closed annular shell disposed around the microwave generator.

2. The semiconductor processing method of claim 1, further comprising:
measuring a magnetic field at a location outside of the magnetic field shield; and
performing a remedial action in response to the measured magnetic field exceeding a threshold.

3. The semiconductor processing method of claim 1, wherein:
the microwave generator includes a housing; and
the magnetic field shield comprises the at least one closed annular shell disposed around the housing of the microwave generator.

4. The semiconductor processing method of claim 1, wherein the at least one closed annular shell has a triangular, rectangular, or higher-order polynomial perimeter, or an oval perimeter.

5. The semiconductor processing method of claim 1, wherein the at least one closed annular shell has a height greater than or equal to a height of the at least one magnet of the microwave generator.

6. The semiconductor processing method of claim 1, wherein the at least one closed annular shell comprises a plurality of nested closed annular shells disposed around the microwave generator.

7. The semiconductor processing method of claim 1, wherein the material of the at least one closed annular shell has a magnetic permeability of at least 1×10⁻⁴ H/m.

8. The semiconductor processing method of claim 1, wherein the material of the at least one closed annular shell comprises mu-metal, permalloy, steel, iron, or nickel.

9. The semiconductor processing method of claim 1, wherein the magnetic field shield further comprises:
a bottom comprising the material with magnetic permeability that is greater than the magnetic permeability of free space;
wherein the bottom is connected with the at least one closed annular shell to form a container within which the at least one magnet of the microwave generator is disposed.

10. A semiconductor processing tool cluster comprising:
a first semiconductor processing tool including a microwave generator comprising at least one magnet and configured to perform semiconductor wafer processing using microwave energy produced by the microwave generator;
a second processing tool configured to perform semiconductor wafer processing using a plasma generated in a process chamber of the second processing tool; and
a magnetic field shield comprising at least one closed annular shell disposed around the microwave generator of the first semiconductor processing tool, the at least one closed annular shell comprising a material with magnetic permeability that is greater than the magnetic permeability of free space.

11. The semiconductor processing tool cluster of claim 10, wherein:
the microwave generator includes a housing; and
the magnetic field shield comprises the at least one closed annular shell disposed around the housing of the microwave generator.

12. The semiconductor processing tool cluster of claim 10, wherein the at least one closed annular shell has a height greater than or equal to a height of the at least one magnet of the microwave generator.

13. The semiconductor processing tool cluster of claim 10, wherein the at least one closed annular shell comprises a plurality of nested closed annular shells disposed around the microwave generator.

14. The semiconductor processing tool cluster of claim 10, wherein the material of the at least one closed annular shell has a magnetic permeability of at least 1×10⁻⁴ H/m.

15. The semiconductor processing tool cluster of claim 10, further comprising:
a magnetometer arranged to measure a magnetic field at a location outside of the magnetic field shield; and
a circuit configured to perform a remedial action based on a magnetic field measurement output by the magnetometer.

16. The semiconductor processing tool cluster of claim 10, wherein:
the first semiconductor processing tool is configured to perform photoresist stripping using the microwave energy produced by the microwave generator; and
the second semiconductor processing tool is configured to perform etching using the plasma generated in the process chamber of the at least one second processing tool.

17. The semiconductor processing tool cluster of claim 10, further comprising:
at least additional semiconductor processing tool;
at least one load lock configured to transfer semiconductor wafers to and from the semiconductor processing tool cluster;
wherein the first semiconductor processing tool, the second semiconductor processing tool, the at least one additional semiconductor processing tool, and the at least one load lock are arranged as a ring with the second semiconductor processing tool next to the first semiconductor processing tool in the ring.

18. A semiconductor processing tool comprising:
a microwave generator comprising a housing and at least one magnet disposed in the housing;
a process chamber;
a waveguide and an applicator connected to guide microwave energy produced by the microwave generator into the process chamber; and
a magnetic field shield comprising at least one closed annular shell disposed around the microwave generator of the first semiconductor processing tool, the at least one closed annular shell comprising a material with magnetic permeability of at least 1×10⁻⁴ H/m.

19. The semiconductor processing tool of claim 18, wherein the material of the at least one closed annular shell comprises mu-metal, permalloy, steel, iron, or nickel.

20. The semiconductor processing tool of claim 18, wherein the magnetic field shield further comprises:
a bottom comprising a material with magnetic permeability of at least 1×10⁻⁴ H/m;
wherein the bottom is connected with the at least one closed annular shell to form a container within which the at least one magnet of the microwave generator is disposed.
